(19) United States
(12) Patent Application Publication
(10) Pub. No.: US 2021/0320085 A1
(43) Pub. Date: Oct. 14, 2021

(54) SEMICONDUCTOR PACKAGE

(71) Applicant: NANYA TECHNOLOGY CORPORATION, New Taipei City (TW)

(72) Inventor: Wu-Der YANG, Taoyuan City (TW)

(21) Appl. No.: 16/845,045

(22) Filed: Apr. 9, 2020

(51) Int. Cl. H01L 25/065

(52) U.S. Cl. CPC H01L 25/0657; H01L 2225/06517; H01L 2225/06586; H01L 2225/06548; H01L 2225/06555; H01L 2225/0652

(57) ABSTRACT

A semiconductor package includes a first substrate, a first semiconductor die, a second semiconductor die, a second substrate, at least one first solder ball, at least one second solder ball, and at least one third solder ball. The first semiconductor die is disposed on the first substrate. The second semiconductor die is disposed on the first semiconductor die. The second substrate is disposed on the second semiconductor die. The first solder ball is vertically between the first substrate and the first semiconductor die. The second solder ball is vertically between the second substrate and the second semiconductor die. The third solder ball is vertically between the first substrate and the second substrate.

### BACKGROUND

### Field of Invention

The present disclosure relates to a semiconductor package.

### Description of Related Art

Dual-die packaging (DPP) technology is widely used to pack two integrated circuit chips in one single package module, such that one single package module is capable of offering a double level of functionality or data storage capacity. Memory chips, such as dynamic random access memory (DRAM) chips, are typically packaged in this way so as to allow one single memory module to offer a double level of data storage capacity. Recently, various kinds of dual-die packaging technologies have been developed and utilized in the semiconductor industry.

Generally, golden wires are widely used to transmit current from a power source to the DRAM chip. However, when a large transient current is required for operation of the DRAM chip (e.g., high frequency operation), the golden wires operated at a high frequency would form a large resistance and hence restricts the transmission of the large transient current. As a result, a transient voltage drop occurs in the DRAM chip and eventually causes chip mis-operation. Accordingly, it is desirable to develop a semiconductor device with an improved functionality to overcome the problem mentioned above.

### SUMMARY

The present disclosure relates in general to a semiconductor package.

According to an embodiment of the present disclosure, the semiconductor package includes a first substrate, a first semiconductor die, a second semiconductor die, a second substrate, at least one first solder ball, at least one second solder ball, and at least one third solder ball. The first semiconductor die is disposed on the first substrate. The second semiconductor die is disposed on the first semiconductor die. The second substrate is disposed on the second semiconductor die. The first solder ball is vertically between the first substrate and the first semiconductor die. The second solder ball is vertically between the second substrate and the second semiconductor die. The third solder ball is vertically between the first substrate and the second substrate.

In some embodiments of the present disclosure, a functional surface of the first semiconductor die faces toward the first substrate.

In some embodiments of the present disclosure, a functional surface of the second semiconductor die faces toward the first substrate.

In some embodiments of the present disclosure, the first solder ball has a smaller size than the third solder ball.

In some embodiments of the present disclosure, the second solder ball has a smaller size than the third solder ball.

In some embodiments of the present disclosure, wherein the third solder ball has a ball height greater than a sum of a total thickness of the first semiconductor die and the second semiconductor die, a ball height of the first solder ball, and a ball height of the second solder ball.

In some embodiments of the present disclosure, the third solder ball extends from the first substrate to the second substrate.

In some embodiments of the present disclosure, the third solder ball is laterally spaced apart from the first semiconductor die and the second semiconductor die.

In some embodiments of the present disclosure, the semiconductor package further includes at least one fourth solder ball on a surface of the first substrate facing away from the third solder ball.

In some embodiments of the present disclosure, the fourth solder ball is electrically connected to the third solder ball.

In some embodiments of the present disclosure, the semiconductor package further includes at least one first copper pillar vertically extending between the first solder ball and the first semiconductor die, and at least one second copper pillar vertically extending between the second solder ball and the second semiconductor die.

In some embodiments of the present disclosure, the semiconductor package further includes an adhesive layer sandwiched between the first semiconductor die and the second semiconductor die.

In some embodiments of the present disclosure, the semiconductor package further includes at least one first redistribution layer vertically between the first semiconductor die and the first solder ball.

In some embodiments of the present disclosure, the semiconductor package further includes at least one second redistribution layer vertically between the second semiconductor die and the second solder ball.

In some embodiments of the present disclosure, the semiconductor package further includes a molding compound encapsulating the first semiconductor die and the second semiconductor die.

In some embodiments of the present disclosure, the molding compound further encapsulates the third solder ball.

In some embodiments of the present disclosure, the semiconductor package further includes at least one through-substrate via (TSV) embedded in the first substrate.

In some embodiments of the present disclosure, the TSV electrically connects the first solder ball and the third solder ball.

In some embodiments of the present disclosure, the semiconductor package further includes at least one TSV embedded in the second substrate.

In some embodiments of the present disclosure, the TSV electrically connects the second solder ball and the third solder ball.

In the aforementioned embodiments of the present disclosure, since golden wires used in the conventional semiconductor packages are replaced by the first solder balls, the second solder ball, and the third solder balls with larger sizes in the present disclosure, the large resistance generated by the golden wires which causes the transient voltage drop in the semiconductor package can be prevented, and thus, for example, the power supply from external electronic devices can be stably provided to the semiconductor package even when a large transient current is needed. Accordingly, the semiconductor package can still perform well even when there is a demand for large transient current.

### BRIEF DESCRIPTION OF THE DRAWINGS

The disclosure can be more fully understood by reading the following detailed description of the embodiments, with reference made to the accompanying drawings as follows:

FIG. 1 is a schematic side view illustrating a semiconductor package according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

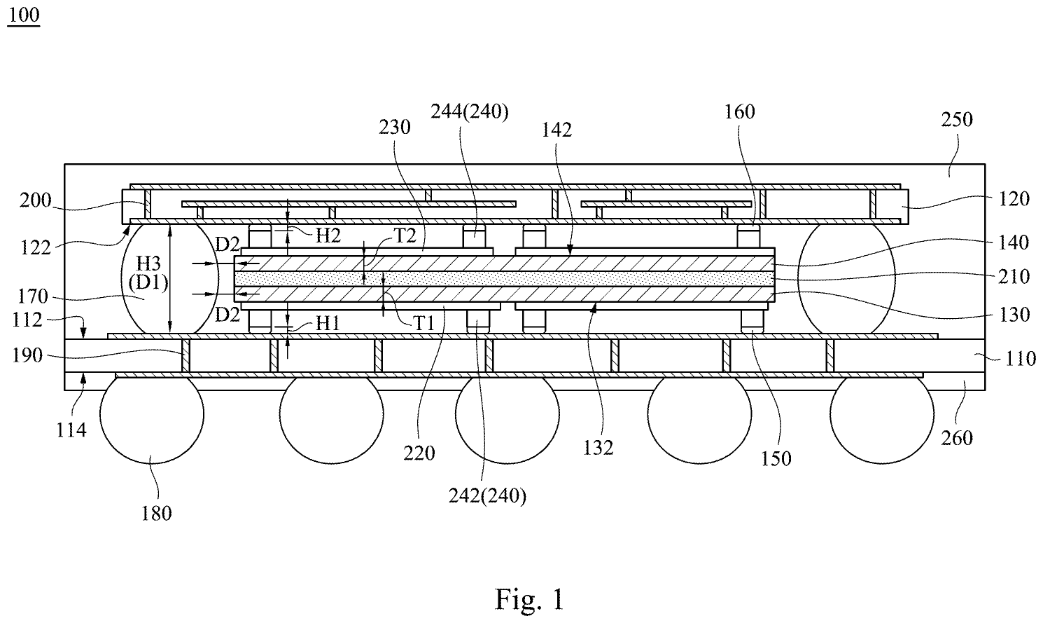

FIG. 1 is a schematic side view illustrating a semiconductor package 100 according to an embodiment of the present disclosure. The semiconductor package 100 includes a first substrate 110, a second substrate 120, a first semiconductor die 130, and a second semiconductor die 140. The first semiconductor die 130 is disposed on the first substrate 110, the second semiconductor die 140 is disposed on the first semiconductor die 130, and the second substrate 120 is disposed on the second semiconductor die 140. In other words, the first semiconductor die 130 and the second semiconductor die 140 are stacked together vertically and sandwiched between the first substrate 110 and the second substrate 120.

The semiconductor package 100 further includes at least one first solder ball 150 and at least one second solder ball 160. In some embodiments, the first solder ball 150 is mounted vertically between the first substrate 110 and the first semiconductor die 130 to electrically connect the first substrate 110 and the first semiconductor die 130. Accordingly, the first semiconductor die 130 can further make electrical connections to other external electronic devices (e.g., the power source) through the first solder ball 150 and the first substrate 110. In some embodiments, the second solder ball 160 is mounted vertically between the second substrate 120 and the second semiconductor die 140 to electrically connect the second substrate 120 and the second semiconductor die 140.

For the purpose of making electrical connections within the semiconductor package 100, in some embodiments, a functional surface 132 of the first semiconductor die 130 (e.g., a surface of the first semiconductor die facing its redistribution layer (RDL) 220) faces toward the first substrate 110, and a functional surface 142 of the second semiconductor die 140 (e.g., a surface of the second semiconductor die facing its RDL 230) faces toward the second substrate 120. As such, the first solder ball 150 and the second solder ball 160 can respectively make electrical connections between the first substrate 110 and the first semiconductor die 130 and between the second substrate 120 and the second semiconductor die 140. It is noted that the “functional surface” herein refers to a surface that has conductive patterns such as conductive traces, conductive lines or conductive layers thereon, e.g., the RDL.

The semiconductor package 100 further includes at least one third solder ball 170 mounted vertically between the first substrate 110 and the second substrate 120 to electrically connect the first substrate 110 and the second substrate 120. Accordingly, the second semiconductor die 140 can be electrically connected to the first substrate 110 through the second solder ball 160 and the third solder ball 170 for further electrical connections to other external electronic devices (e.g., the power source). As a result, a dual-die package including the first semiconductor die 130 and the second semiconductor die 140 can be functionalized due to such a configuration of the electrical connections.

Since golden wires used in the conventional semiconductor packages are replaced by the first solder balls, the second solder ball, and the third solder balls with larger sizes in the present disclosure, the large resistance caused by the golden wires which causes the transient voltage drop in the semiconductor package can be prevented, and thus, for example, the power supply from external electronic devices can be stably provided to the semiconductor package even when a large transient current occurs.

In some embodiments, the third solder ball 170 extends from the first substrate 110 to the second substrate 120. More specifically, the third solder ball 170 extends from an inner surface 112 of the first substrate 110 to an inner surface 122 of the second substrate 120. Stated differently, a distance D1 between the inner surface 112 of the first substrate 110 and the inner surface 122 of the second substrate 120 is substantially identical to a ball height H3 of the third solder ball 170. In some embodiments, a size of the third solder ball 170 is larger than a size of the first solder ball 150 and a size of the second solder ball 160. In some embodiments, the ball height H3 of the third solder ball 170 may depend on a sum of a total thickness of the first semiconductor die 130 and the second semiconductor die 140 and a total ball height of the first solder ball 150 and the second solder ball 160. For example, the ball height H3 of the third solder ball 170 may be substantially identical to a sum of a thickness T1 of the first semiconductor die 130, a thickness T2 of the second semiconductor die 140, a ball height H1 of the first solder ball 150, and a ball height H2 of the second solder ball 160. As such, deformation of the semiconductor package 100 can be prevented.

In some embodiments, the third solder ball 170 is horizontally spaced apart from the dual-die package including the first semiconductor die 130 and the second semiconductor die 140. In some embodiments, a distance D2 between the third solder ball 170 and the first semiconductor die 130 (or the second semiconductor die 140) is in a range from about 200 μm to about 1000 μm to prevent an unexpected contact between the third solder ball 170 and the first semiconductor die 130 (or the second semiconductor die 140) and to keep the semiconductor package 100 in a small size. For example, if the distance D2 is smaller than about 200 μm, the third solder ball 170 may accidentally be in contact with the first semiconductor die 130 (or the second semiconductor die 140); and if the distance D2 is larger than about 1000 μm, the size of the semiconductor package 100 may be difficult to decrease.

In some embodiments, the semiconductor package 100 further includes at least one fourth solder ball 180 on a surface 114 of the first substrate 110 facing away from the third solder ball 170. In other words, the fourth solder ball 180 is mounted on an outer surface of the first substrate 110. In some embodiments, the fourth solder ball 180 is electrically connected to the first solder ball 150 and the third solder ball 170, such that the first semiconductor die 130 and the second semiconductor die 140 can be electrically connected to other external electronic devices.

In some embodiments, a number of each of the first solder ball 150, the second solder ball 160, the third solder ball 170, and the fourth solder ball 180 may be plural. For example, as shown in FIG. 1, a number of each of the first solder ball 150 and the second solder ball 160 is four, a number of the third solder ball 170 is two, and a number of the fourth solder ball 180 is five. However, since FIG. 1 is a schematic side view of the semiconductor package 100, there may actually be more solder balls in total. As the number of each of the first solder ball 150 and the second solder ball 160 is larger, the current transmitted from and/or to the first semiconductor die 130 and the second semiconductor die 140 may be higher so as to accelerate the operation of the semiconductor package 100. In addition, the configuration of the solder balls may be bilaterally symmetrical from the side view of the semiconductor package 100 (e.g., from the side view shown in FIG. 1) so as to maintain a balance of the semiconductor package 100.

In some embodiments, the semiconductor package 100 further includes at least one first conductive structure 190 and at least one second conductive structure 200. The first conductive structure 190 is embedded in the first substrate 110 (e.g., a through-substrate via (TSV) extending through a full thickness of the first substrate 110) to connect the first solder ball 150 and the fourth solder ball 180, such that current can be transmitted between the external electronic devices and the first semiconductor die 130. The second conductive structure 200 is embedded in the second substrate 120 (e.g., a through-substrate via (TSV) extending through a full thickness of the first substrate 120) to connect the second solder ball 160 and the third solder ball 170, such that current can be transmitted between the external electronic devices and the second semiconductor die 140. In some embodiments, each of the first conductive structure 190 and the second conductive structure 200 may include at least one horizontal portion and at least one vertical portion connecting with each other.

In some embodiments, the semiconductor package 100 further includes an adhesive layer 210 sandwiched between the first semiconductor die 130 and the second semiconductor die 140. The adhesive layer 210 is configured to adhere the first semiconductor die 130 to the second semiconductor die 140. For example, the adhesive layer 210 adheres a surface facing away from the functional surface 132 of the first semiconductor die 130 to a surface facing away from the functional surface 142 of the second semiconductor die 140, such that the functional surface 132 of the first semiconductor die 130 and the functional surface 142 of the second semiconductor die 140 can respectively face toward the first substrate 110 and the second substrate 120 to further make electrical connections to the first substrate 110 and the second substrate 120.

In some embodiments, the semiconductor package 100 further includes at least one first redistribution layer 220 and at least one second redistribution layer 230. The first redistribution layer 220 is disposed on the functional surface 132 of the first semiconductor die 130 and vertically between the first semiconductor die 130 and the first solder ball 150. The second redistribution layer 230 is disposed on the functional surface 142 of the second semiconductor die 140 and vertically between the second semiconductor die 140 and the second solder ball 160. In some embodiments, the semiconductor package 100 further includes a plurality of conductive pillar structures 240 (e.g., cupper pillar) on the first redistribution layer 220 and the second redistribution layer 230, such that the first solder ball 150 and the second solder ball 160 can be mounted thereon. For example, the semiconductor package 100 includes at least one first copper pillar 242 vertically extending between the first solder ball 150 and the first semiconductor die 130, and at least one second copper pillar 244 vertically extending between the second solder ball 160 and the second semiconductor die 150.

As mentioned above, the ball height H3 of the third solder ball 170 may depend on a sum of a total thickness of the first semiconductor die 130 and the second semiconductor die 140 and a total ball height of the first solder ball 150 and the second solder ball 160. In the embodiment which the semiconductor package 100 further includes the adhesive layer 210, the first redistribution layer 220, the second redistribution layer 230, and the conductive pillar structures 240, the ball height H3 of the third solder ball 170 may further depend on a total thickness of the adhesive layer 210, the first redistribution layer 220, the second redistribution layer 230, and the conductive pillar structures 240.

In some embodiments, the semiconductor package 100 further includes a molding compound 250 encapsulating the first semiconductor die 130 and the second semiconductor die 140. In some embodiments, the molding compound 250 further encapsulates the second substrate 120, the first solder ball 150, the second solder ball 160, and the third solder ball 170. The molding compound 250 is configured to protect the above elements from being over-exposed to an external environment. In some embodiments, the semiconductor package 100 further includes an encapsulating layer 260 disposed on a surface 114 of the first substrate 110 on which the fourth solder ball 180 is mounted. The molding layer 260 can protect the connecting portion of the first conductive structure 190 and the fourth solder ball 180. Therefore, a portion of the fourth solder ball 180 is embedded in the molding layer 260.

According to the aforementioned embodiments of the present disclosure, through the configuration of the first solder balls, the second solder ball, and the third solder balls, the large resistance resulting from golden wires which causes the transient voltage drop in the semiconductor package can be prevented, and thus the semiconductor package can still perform well even when there is a demand for large transient current.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. A semiconductor package, comprising:
a first substrate;
a first semiconductor die disposed on the first substrate;
a second semiconductor die disposed on the first semiconductor die;
a second substrate disposed on the second semiconductor die;
at least one first solder ball vertically between the first substrate and the first semiconductor die;
at least one second solder ball vertically between the second substrate and the second semiconductor die;
at least one third solder ball vertically between the first substrate and the second substrate, wherein the third solder ball has a curved sidewall extending from a top to a bottom of the third solder ball; and
a molding compound surrounding the first semiconductor die and the second semiconductor die, wherein an entirety of the curved sidewall of the third solder ball is in contact with the molding compound.

2. The semiconductor package of claim 1, wherein a functional surface of the first semiconductor die faces toward the first substrate.

3. The semiconductor package of claim 1, wherein a functional surface of the second semiconductor die faces toward the second substrate.

4. The semiconductor package of claim 1, wherein the first solder ball has a smaller size than the third solder ball.

5. The semiconductor package of claim 1, wherein the second solder ball has a smaller size than the third solder ball.

6. The semiconductor package of claim 1, wherein the third solder ball has a ball thickness greater than a sum of a total thickness of the first semiconductor die and the second semiconductor die, a ball thickness of the first solder ball, and a ball thickness of the second solder ball, wherein the first semiconductor die, the third solder ball, and the second semiconductor die is stacked along a first direction, and the ball thicknesses of the first solder ball, the second solder ball, and the third solder ball are thicknesses in the first direction.

7. The semiconductor package of claim 1, wherein the third solder ball extends from the first substrate to the second substrate.

8. The semiconductor package of claim 1, wherein the third solder ball is laterally spaced apart from the first semiconductor die and the second semiconductor die.

9. The semiconductor package of claim 1, further comprising at least one fourth solder ball on a surface of the first substrate facing away from the third solder ball.

10. The semiconductor package of claim 9, wherein the fourth solder ball is electrically connected to the third solder ball.

11. The semiconductor package of claim 9, further comprising at least one first copper pillar vertically extending between the first solder ball and the first semiconductor die, and at least one second copper pillar vertically extending between the second solder ball and the second semiconductor die.

12. The semiconductor package of claim 1, further comprising an adhesive layer sandwiched between the first semiconductor die and the second semiconductor die.

13. The semiconductor package of claim 1, further comprising at least one first redistribution layer vertically between the first semiconductor die and the first solder ball.

14. The semiconductor package of claim 1, further comprising at least one second redistribution layer vertically between the second semiconductor die and the second solder ball.

15. (canceled)

16. The semiconductor package of claim 1, wherein the molding compound further encapsulates the third solder ball.

17. The semiconductor package of claim 1, further comprising at least one through-substrate via (TSV) embedded in the first substrate.

18. The semiconductor package of claim 17, wherein the TSV electrically connects the first solder ball and the third solder ball.

19. The semiconductor package of claim 1, further comprising at least one TSV embedded in the second substrate.

20. The semiconductor package of claim 19, wherein the TSV electrically connects the second solder ball and the third solder ball.
